(19) United States
(12) Patent Application Publication
(10) Pub. No.: US 2010/0147356 A1
(43) Pub. Date: Jun. 17, 2010

(54) Thin film solar cell string

(76) Inventor: Jeffrey S. Britt, Tucson, AZ (US)

Correspondence Address: KOLISCH HARTWELL, P.C., 200 PACIFIC BUILDING, 520 SW YAMHILL STREET, PORTLAND, OR, 97204, US

(21) Appl. No.: 12/587,111

(22) Filed: Sep. 30, 2009

Related U.S. Application Data
(60) Provisional application No. 61/101,517, filed on Sep. 30, 2008.

(51) Int. Cl. H01L 31/042

(52) U.S. Cl. 136/244

(57) ABSTRACT

Thin film photovoltaic cells and strings of cells that may be electrically joined in series by a conductive carrier web that underlies the positive polarity side (bottom side) of the cells. Electrical contact between the positive polarity side of a cell and the carrier web may be made through electrically conductive material such as conductive adhesive disposed between the carrier web and one or more portions of the bottom surface of each cell. Electrical contact between the negative polarity (top side) of a cell and the carrier web may be made through one or more apertures formed in the cell. An electrically conductive material may be disposed in the apertures for this purpose, in conjunction with a dielectric to line the aperture and avoid an electrical short between the opposite polarities of a given cell.

### CROSS-REFERENCE TO RELATED APPLICATION(S)

This application claims priority under 35 U.S.C. §119(e) to U.S. Provisional Patent Application Ser. No. 61/101,517 filed on Sep. 30, 2008, and entitled “Thin Film Solar Cell String.” The complete disclosure of the above-identified patent application is hereby incorporated by reference for all purposes.

### BACKGROUND

The field of photovoltaics generally relates to multi-layer materials that convert sunlight directly into DC electrical power. The basic mechanism for this conversion is the photovoltaic effect, first observed by Antoine-César Becquerel in 1839, and first correctly described by Einstein in a seminal 1905 scientific paper for which he was awarded a Nobel Prize for physics. In the United States, photovoltaic (PV) devices are popularly known as solar cells or PV cells. Solar cells are typically configured as a cooperating sandwich of p-type and n-type semiconductors, in which the n-type semiconductor material (on one “side” of the sandwich) exhibits an excess of electrons, and the p-type semiconductor material (on the other “side” of the sandwich) exhibits an excess of holes, each of which signifies the absence of an electron. Near the p-n junction between the two materials, valence electrons from the n-type layer move into neighboring holes in the p-type layer, creating a small electrical imbalance inside the solar cell. This results in an electric field in the vicinity of the metallurgical junction that forms the electronic p-n junction.

When an incident photon excites an electron in the cell into the conduction band, the excited electron becomes unbound from the atoms of the semiconductor, creating a free electron/hole pair. Because, as described above, the p-n junction creates an electric field in the vicinity of the junction, electron/hole pairs created in this manner near the junction tend to separate and move away from junction, with the electron moving toward the electrode on the n-type side, and the hole moving toward the electrode on the p-type side of the junction. This creates an overall charge imbalance in the cell, so that if an external conductive path is provided between the two sides of the cell, electrons will move from the n-type side back to the p-type side along the external path, creating an electric current. In practice, electrons may be collected from at or near the surface of the n-type side by a conducting grid that covers a portion of the surface, while still allowing sufficient access into the cell by incident photons.

Such a photovoltaic structure, when appropriately located electrical contacts are included and the cell (or a series of cells) is incorporated into a closed electrical circuit, forms a working PV device. As a standalone device, a single conventional solar cell is not sufficient to power most applications. As a result, solar cells are commonly arranged into PV modules, or “strings,” by connecting the front of one cell to the back of another, thereby adding the voltages of the individual cells together in electrical series. Typically, a significant number of cells are connected in series to achieve a usable voltage. The resulting DC current then may be fed through an inverter, where it is transformed into AC current at an appropriate frequency, which is chosen to match the frequency of AC current supplied by a conventional power grid. In the United States, this frequency is 60 Hertz (Hz), and most other countries provide AC power at either 50 Hz or 60 Hz.

One particular type of solar cell that has been developed for commercial use is a “thin-film” PV cell. In comparison to other types of PV cells, such as crystalline silicon PV cells, thin-film PV cells require less light-absorbing semiconductor material to create a working cell, and thus can reduce processing costs. Thin-film based PV cells also offer reduced cost by employing previously developed deposition techniques for the electrode layers, where similar materials are widely used in the thin-film industries for protective, decorative, and functional coatings. Common examples of low cost commercial thin-film products include water impermeable coatings on polymer-based food packaging, decorative coatings on architectural glass, low emissivity thermal control coatings on residential and commercial glass, and scratch and anti-reflective coatings on eyewear. Adopting or modifying techniques that have been developed in these other fields has allowed a reduction in development costs for PV cell thin-film deposition techniques.

Furthermore, thin-film cells have exhibited efficiencies approaching 20%, which rivals or exceeds the efficiencies of the most efficient crystalline cells. In particular, the semiconductor material copper indium gallium diselenide (CIGS) is stable, has low toxicity, and is truly a thin film, requiring a thickness of less than two microns in a working PV cell. As a result, to date CIGS appears to have demonstrated the greatest potential for high performance, low cost thin-film PV products, and thus for penetrating bulk power generation markets. Other semiconductor variants for thin-film PV technology include copper indium diselenide, copper indium disulfide, copper indium aluminum diselenide, and cadmium telluride.

Some thin-film PV materials may be deposited either on rigid glass substrates, or on flexible substrates. Glass substrates are relatively inexpensive, generally have a coefficient of thermal expansion that is a relatively close match with the CIGS or other absorber layers, and allow for the use of vacuum deposition systems. However, when comparing technology options applicable during the deposition process, rigid substrates suffer from various shortcomings during processing, such as a need for substantial floor space for processing equipment and material storage, expensive and specialized equipment for heating glass uniformly to elevated temperatures at or near the glass annealing temperature, a high potential for substrate fracture with resultant yield loss, and higher heat capacity with resultant higher electricity cost for heating the glass. Furthermore, rigid substrates require increased shipping costs due to the weight and fragile nature of the glass. As a result, the use of glass substrates for the deposition of thin films may not be the best choice for low-cost, large-volume, high-yield, commercial manufacturing of multilayer functional thin-film materials such as photovoltaics.

In contrast, roll-to-roll processing of thin flexible substrates allows for the use of compact, less expensive vacuum systems, and of non-specialized equipment that already has been developed for other thin film industries. PV cells based on thin flexible substrate materials also exhibit a relatively high tolerance to rapid heating and cooling and to large thermal gradients (resulting in a low likelihood of fracture or failure during processing), require comparatively low shipping costs, and exhibit a greater ease of installation than cells based on rigid substrates. Additional details relating to the composition and manufacture of thin film PV cells of a type suitable for use with the presently disclosed methods and apparatus may be found, for example, in U.S. Pat. Nos. 6,310,281, 6,372,538, and 7,194,197, all to Wendt et al. These patents are hereby incorporated into the present disclosure by reference for all purposes.

As noted previously, a significant number of PV cells often are connected in series to achieve a usable voltage, and thus a desired power output. Such a configuration is often called a “string” of PV cells. Due to the different properties of crystalline substrates and flexible thin film substrates, the electrical series connection between cells may be constructed differently for a thin film cell than for a crystalline cell, and forming reliable series connections between thin film cells poses several challenges. For example, soldering (the traditional technique used to connect crystalline solar cells) directly on thin film cells exposes the PV coatings of the cells to damaging temperatures, and the organic-based silver inks typically used to form a collection grid on thin film cells may not allow strong adherence by ordinary solder materials in any case. Thus, PV cells often are joined with wires or conductive tabs attached to the cells with an electrically conductive adhesive (ECA), rather than by soldering.

However, even when wires or tabs are used to form inter-cell connections, the extremely thin coatings and potential flaking along cut PV cell edges introduces opportunities for shorting (power loss) wherever a wire or tab crosses over a cell edge. Furthermore, the conductive substrate on which the PV coatings are deposited, which typically is a metal foil, may be easily deformed by thermomechanical stress from attached wires and tabs. This stress can be transferred to weakly-adhering interfaces, which can result in delamination of the cells. In addition, adhesion between the ECA and the cell back side, or between the ECA and the conductive grid on the front side, can be weak, and mechanical stress may cause separation of the wires or tabs at these locations. Also, corrosion can occur between the molybdenum or other coating on the back side of a cell and the ECA that joins the tab to the solar cell there. This corrosion may result in a high-resistance contact or adhesion failure, leading to power losses.

Advanced methods of joining thin film PV cells with conductive tabs or ribbons may largely overcome the problems of electrical shorting and delamination, but may require undesirably high production costs to do so. Furthermore, all such methods—no matter how robust—require that at least some portion of the PV string be covered by a conductive tab, which blocks solar radiation from striking that portion of the string and thus reduces the efficiency of the system. As a result, there is a need for improved methods of interconnecting PV cells into strings, and for improved strings of interconnected cells. Specifically, there is a need for strings and methods of their formation that reduce interconnection costs and reduce the fraction of each PV cell that is covered by the interconnection mechanism, while maintaining or improving the ability of the cell to withstand stress.

### SUMMARY

The present teachings disclose thin film photovoltaic cells and strings of cells that may be electrically joined in series by a conductive carrier web that underlies the positive polarity side (bottom side) of the cells. Electrical contact between the positive polarity side of a cell and the carrier web may be made through electrically conductive material such as conductive adhesive disposed between the carrier web and one or more portions of the bottom surface of each cell. Electrical contact between the negative polarity (top side) of a cell and the carrier web may be made through one or more apertures formed in the cell. An electrically conductive material such as an electrically conductive adhesive or a conducting metal may be disposed in the apertures for this purpose, in conjunction with a dielectric to line the aperture and avoid an electrical short between opposite polarities of a given cell.

### BRIEF DESCRIPTION OF THE DRAWINGS

FIGS. 1A and 1B are a sequence of end cross-sectional views showing a length of thin-film PV material being processed into discrete solar cells that may be connected in electrical series, in accordance with aspects of the present disclosure.

FIG. 2 is a sequence of end cross-sectional views showing a modification of the process shown in FIGS. 1A and 1B.

FIG. 3 is a sequence of top views showing a length of thin-film PV material being processed into several discrete solar cells, in accordance with the processing steps shown in FIGS. 1A and 1B.

FIG. 4 is a sequence of top views showing a patterned carrier web being prepared and integrated with the solar cells depicted in FIG. 3.

FIG. 5 is a sequence of top views showing a patterned carrier web being prepared and integrated with solar cells in a modified process from the procedure shown in FIG. 4.

FIG. 6 is a end cross-sectional view showing the patterned carrier web of FIG. 5 integrated with two thin-film solar cells to connect the cells in electrical series.

FIG. 7 is a sequence of end cross-sectional views showing an alternative method of processing thin-film PV material into several discrete cells that may be connected in electrical series, in accordance with aspects of the present disclosure.

FIGS. 8A-C are a sequence of top and bottom views showing the thin-film PV material of FIG. 7 being processed into discrete cells in preparation for their integration with an underlying carrier web.

FIG. 9 is a sequence of top views showing an alternative patterned carrier web being prepared and integrated with the thin-film PV cells of FIGS. 7 and 8.

FIG. 10 is an end cross-sectional view showing the patterned carrier web of FIG. 9 integrated with two thin-film solar cells of the type depicted in FIG. 7, to connect the cells in electrical series.

### DETAILED DESCRIPTION

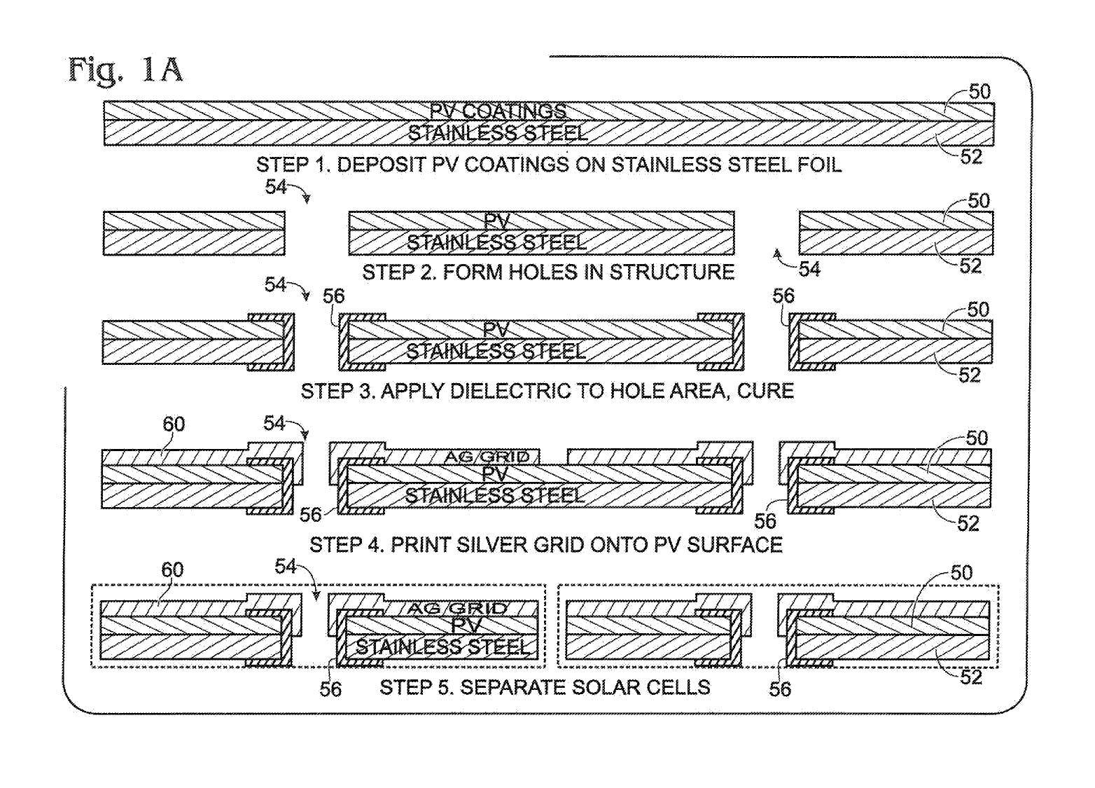

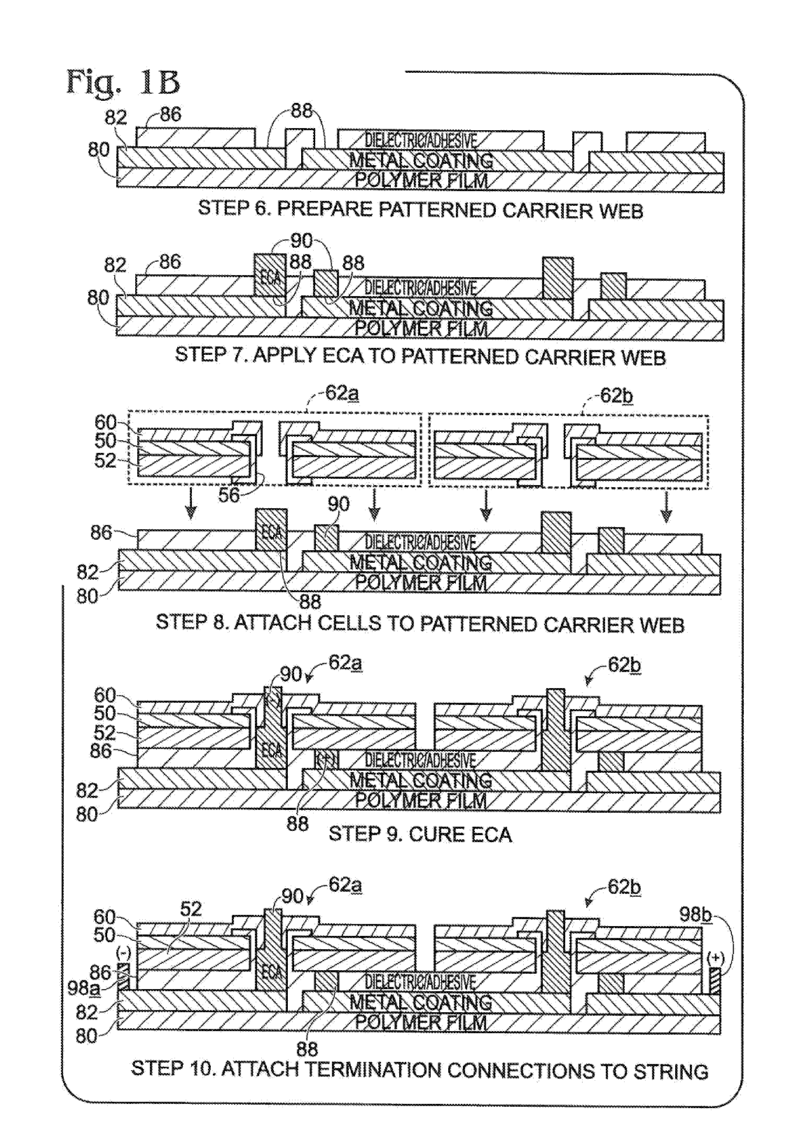

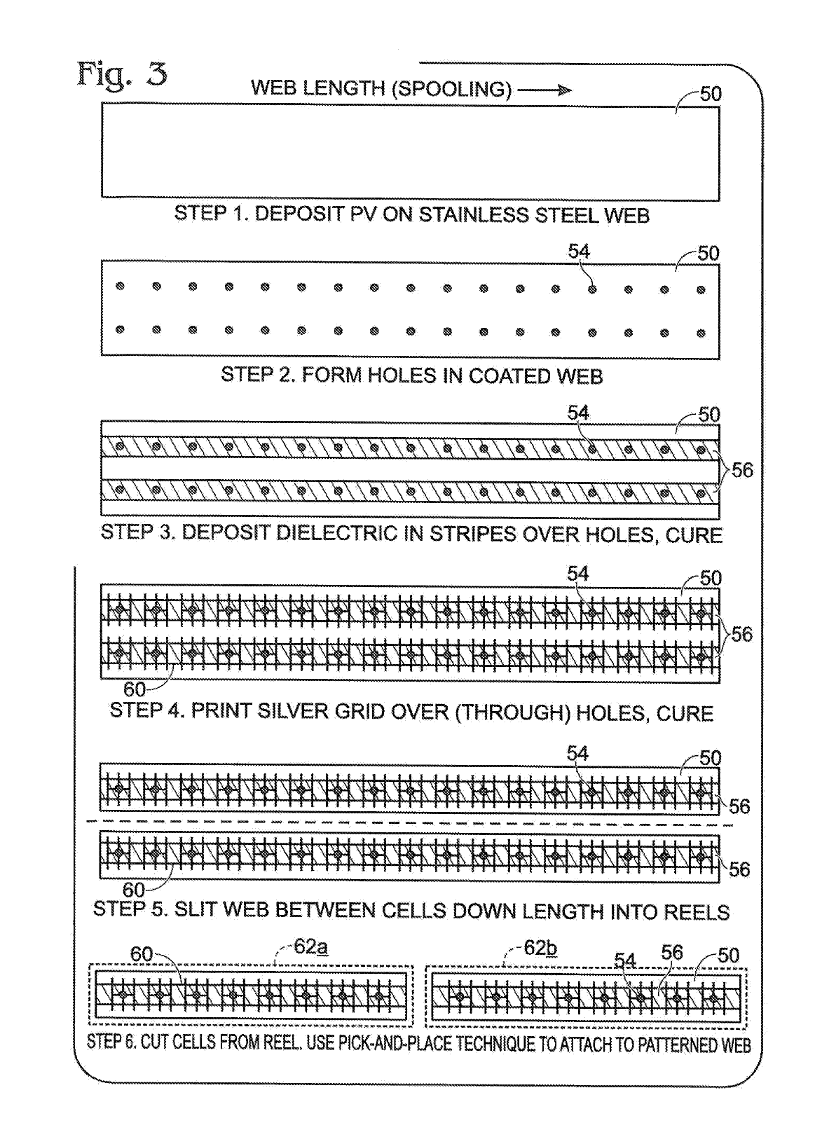

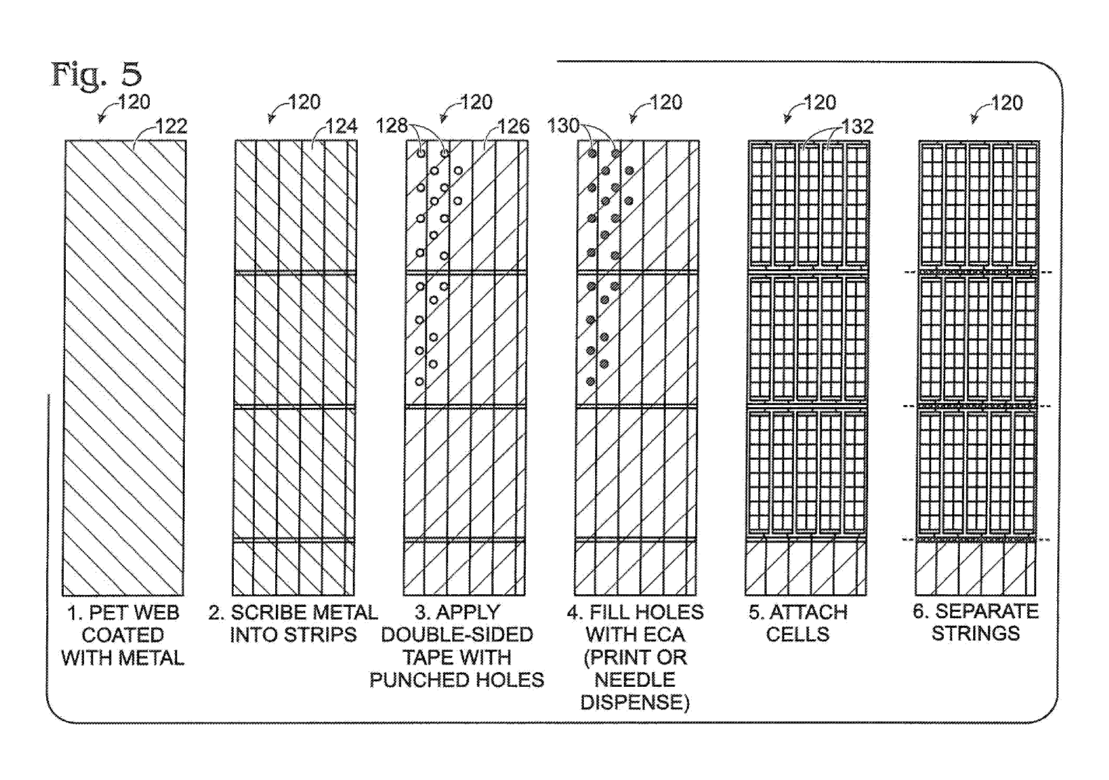

FIGS. 1A and 3 show the preparation of PV cells that may be electrically connected in accordance with aspects of this disclosure. FIG. 1A is a sequence of end cross-sectional views showing a length of thin-film PV material being processed into discrete solar cells. FIG. 3 shows a sequence of top views depicting the same process. In step 1 of FIGS. 1 and 5, PV material 50 is deposited on top of a thin substrate 52. The deposition process of step 1 typically involves sequentially depositing multiple thin layers of different materials onto the substrate in a roll-to-roll process in which the substrate travels from a pay-out roll to a take-up roll, traveling through a series of deposition regions between the two rolls. The PV material then may be cut to cells of any desired size, and the cells may be connected in electrical series according to aspects of this disclosure.

The substrate material in a roll-to-roll process is generally thin, flexible, and can tolerate a relatively high-temperature environment. Suitable materials include, for example, a high temperature polymer such as polyimide, or a thin metal such as stainless steel or titanium, among others. Sequential layers typically are deposited onto the substrate in individual processing chambers by various processes such as sputtering, evaporation, vacuum deposition, and/or printing. These layers may include a molybdenum (Mo) or chromium/molybdenum (Cr/Mo) back contact layer; an absorber layer of material such as copper indium diselenide, copper indium disulfide, copper indium aluminum diselenide, or copper indium gallium diselenide (CIGS); a buffer layer such as a layer of cadmium sulfide (CdS); and a transparent conducting oxide (TCO) layer to conduct photo-generated current to the collection grid. Further details regarding deposition of PV coatings, including possible alternative layering materials, layer thicknesses, and suitable application processes for each layer are described, for example, in U.S. Pat. No. 7,194,197.

Step 2 of FIGS. 1A and 3 shows the formation of apertures 54 through the PV material previously formed in step 1. As FIG. 1A shows, the PV cells each have a top surface and a bottom surface, and the apertures formed in step 2 extend entirely through the PV cells from the top surface to the bottom surface. These apertures may be formed in a variety of ways, such as with a pulsed or continuous laser, with high-pressure water jets, or by mechanical punching. As will be described in more detail below, electrically conductive material disposed within these apertures may be used to electrically connect the top surface of each cell with the bottom surface of an adjacent cell, thus forming an electrical series connection.

As shown in step 3 of FIGS. 1A and 3, dielectric material 56 is applied to the apertures. This is designed to prevent electrical contact between the inner surface of the aperture and the electrically conductive material that will later be placed in the aperture, to avoid a short circuit between the two opposite polarity sides of any particular PV cell. As can be seen in step 3 of FIG. 3, the dielectric material may be applied over the apertures as a liquid, so that it naturally penetrates the apertures to coat their inner surfaces. The dielectric then may be cured, for example, through the application of pressure and/or heat, to fix its location in and around the apertures.

In step 4 of FIGS. 1A and 3, an electrically conductive grid 60 is deposited onto the top surface of the PV cells. Grid 60 collects electric current from the top surface of the cells, and is usually constructed primarily from silver (Ag) or some other conductive metal. The grid may be, for example, a silver-based ink deposited through a printing process. As indicated at step 4 of FIG. 1A, the grid material may extend partially down into the apertures of the PV cells. To facilitate this, additional grid material may be deposited in the vicinity of each aperture, relative to the amount of material deposited to construct other portions of the collection grid. In step 5 of FIGS. 1A and 3, the PV material is cut lengthwise to form two similar reels of PV material, each of which includes all of the elements formed in steps 1-4 as described previously. In step 6, shown in FIG. 3, the reels are cut into individual working PV cells 62a and 62b.

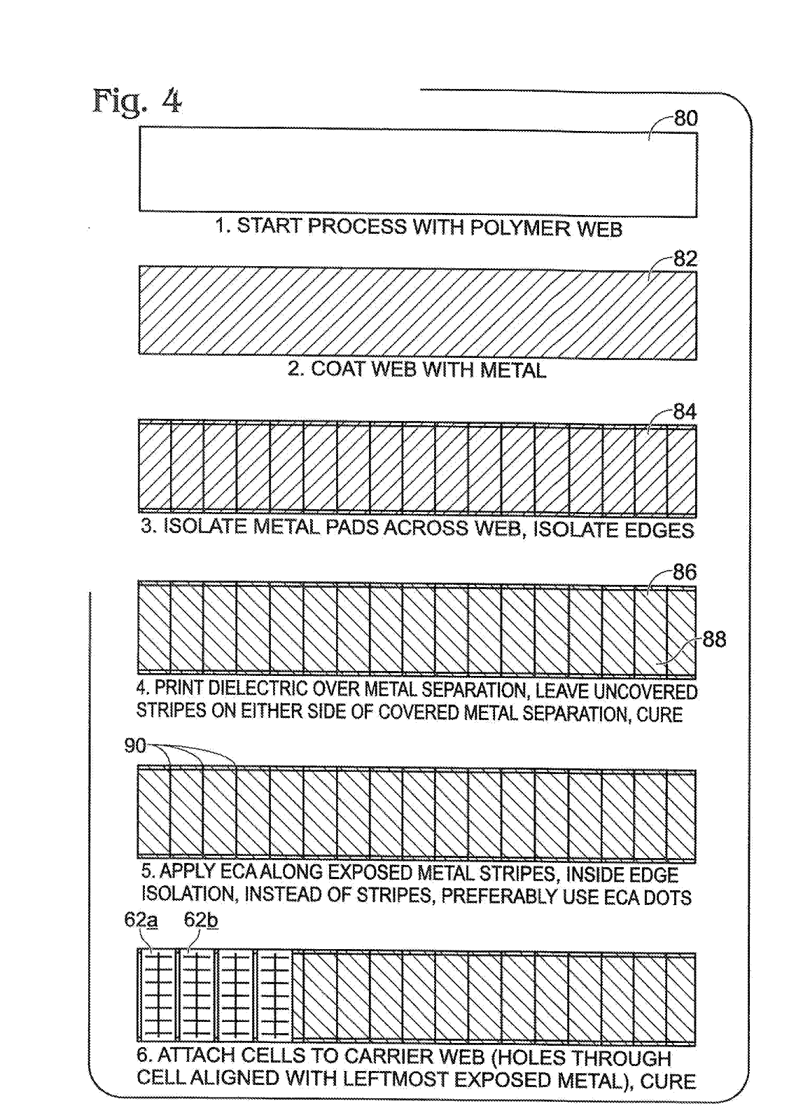

FIG. 4 includes a sequence of top views showing the preparation of a patterned carrier web and integration of the carrier web with the PV cells developed in FIGS. 1A and 3. As indicated in steps 1-2 of FIG. 4, the carrier web typically includes a polymer substrate 80 coated with a conductive material such as a metal. As shown in step 3 of FIG. 4, the metal layer of the carrier web is then divided into electrically isolated sections disposed between the edges of the web. This is typically accomplished by scribing or etching the metal to create isolated sections with desired dimensions.

As shown in step 4 of FIG. 4, a dielectric material 86 (shown as a relatively darker shade) is applied to the carrier web after it has been scribed. This dielectric covers the scribed regions between isolated conductive sections and also the interior portion of each section, while leaving uncovered conductive regions 88 (shown as a relatively lighter shade) on either side of the dielectric covering the scribed regions. In step 5 of FIG. 4, an electrically conductive adhesive 90 is applied, either in the form of stripes or dots, to the exposed conductive stripes that were left uncovered in step 4. Finally, in step 6 of FIG. 4, PV cells are attached to the carrier web, with the apertures in each cell aligned with the exposed conductive regions of the carrier web.

FIG. 1B includes a sequence of side cross-sectional views showing further details of the preparation of the carrier web and its integration with a pair of adjacent PV cells as described in the previous paragraph. Step 6 of FIG. 1B shows polymer substrate 80 of the carrier web coated with a conductive metal 82 that has been scribed in two locations. Dielectric material 86 has been applied to the carrier web in step 6, to cover the metal coating while leaving uncovered conductive regions 88 on either side of each scribed region. In step 7 of FIG. 1B, electrically conductive adhesive 90 is applied to the exposed conductive regions. In step 7 the conductive adhesive can be either stripes running the complete length of a scribed groove, or dots of adhesive placed at one or more desired locations within each groove.

In step 8 of FIG. 1B, a pair of PV cells 62a and 62b of the type described above and shown in FIGS. 1A and 3 are attached to the prepared carrier web. As step 8 indicates, the cells are attached so that the electrically conductive adhesive to one side of each scribed groove penetrates the aperture(s) of the cell and makes electrical contact with the metallic collection grid at the top surface of the cell. This establishes electrical contact between a portion of the carrier web and the negative polarity surface of the corresponding cell. The cells are attached also so that the electrically conductive adhesive to the other side of each scribed groove makes direct contact with the underlying conductive substrate of the cell, establishing an electrical connection between an adjacent portion of the carrier web and the positive polarity surface of the corresponding cell. In this manner, the two adjacent PV cells are connected in electrical series.

Steps 9 and 10 of FIG. 1B show how a string of two adjacent PV cells can be finalized for integration into an electrical circuit. This is merely an exemplary depiction, because in practice, more than two cells are typically connected into a string, as indicated in step 6 of FIG. 4. In step 9 of FIG. 1B, the electrically conductive adhesive that electrically connects the two surfaces of the PV cells to the carrier web is cured, typically by pressure and/or heating. In step 10 of FIG. 1B, termination connections 98a and 98b are applied at each lateral edge of the string, so that the connected PV cells can be integrated into a circuit for supplying solar power.

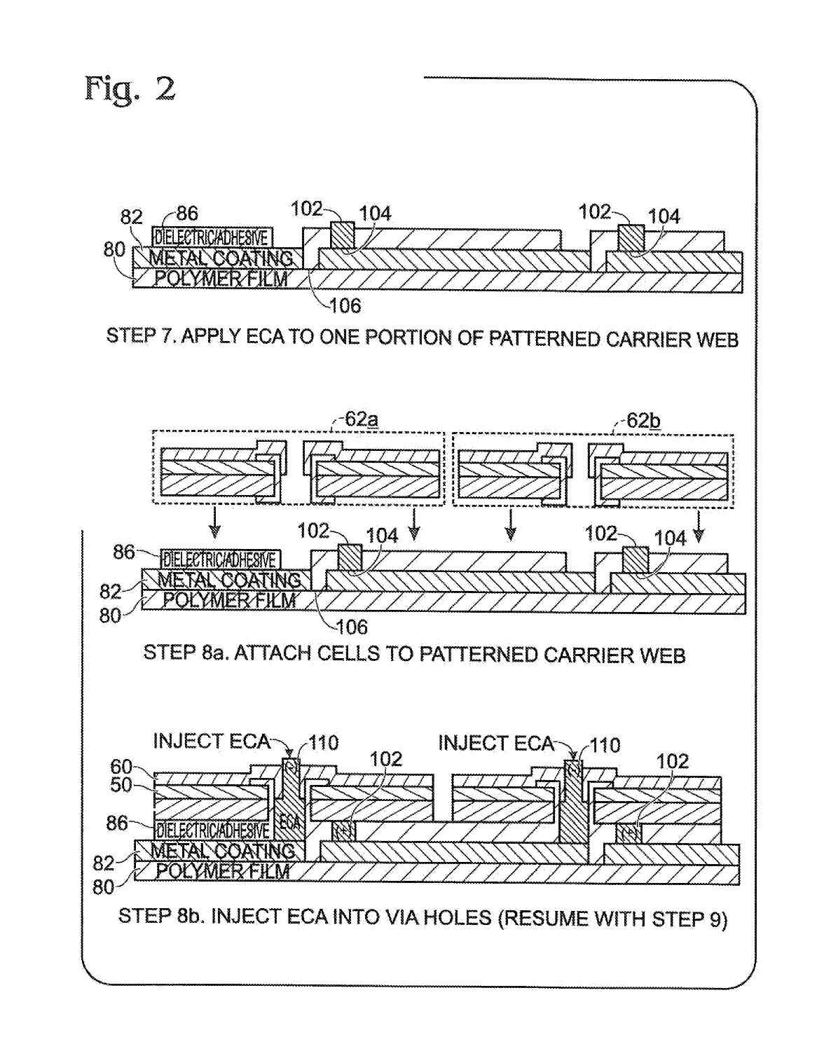

FIG. 2 shows an alternative method of establishing the electrical connection between PV cells of the type shown in FIGS. 1A and 3 and a carrier web of the type shown in steps 1-4 of FIG. 4. More specifically, FIG. 2 shows alternative processing steps to steps 7 and 8 of FIG. 1B. In alternative step 7 of FIG. 2, a first portion 102 of electrically conductive adhesive is applied only to the exposed region 104 on one side (the right side in FIG. 2) of scribed regions 106 of the carrier web. As before, this adhesive can be applied either in continuous stripes, or in discrete dots within the exposed region. In alternative step 8a, a pair of PV cells is attached to the carrier web, establishing electrical contact only between the bottom, positive polarity side of each cell and the carrier web. In step 8b, a second portion 110 of electrically conductive adhesive is injected or otherwise applied to the apertures in the PV cells, establishing electrical contact between the top, negative polarity side of each cell and the carrier web. The connected cells then may be finalized for integration into a circuit in the same manner shown in steps 9 and 10 of FIG. 1B.

FIG. 5 includes a sequence of top views showing alternative processing steps for preparing a carrier web and integrating it with a plurality of PV cells such as those depicted in FIGS. 1A and 3. In steps 1 and 2 of FIG. 5, carrier web 120 is formed by coating a polymer substrate with a metal 122 and then scribing the metal into electrically isolated strips 124. In steps 3 and 4 of FIG. 5, double-sided tape 126 including a plurality of holes 128 formed in the tape is applied to the top surface of the carrier web, and the holes are filled with electrically conductive adhesive 130. The holes and the conductive adhesive are disposed at each side of the scribed regions, and are configured to provide electrical contact between the top and bottom surfaces of the PV cells and the carrier web, as has been described previously and depicted in FIG. 1B.

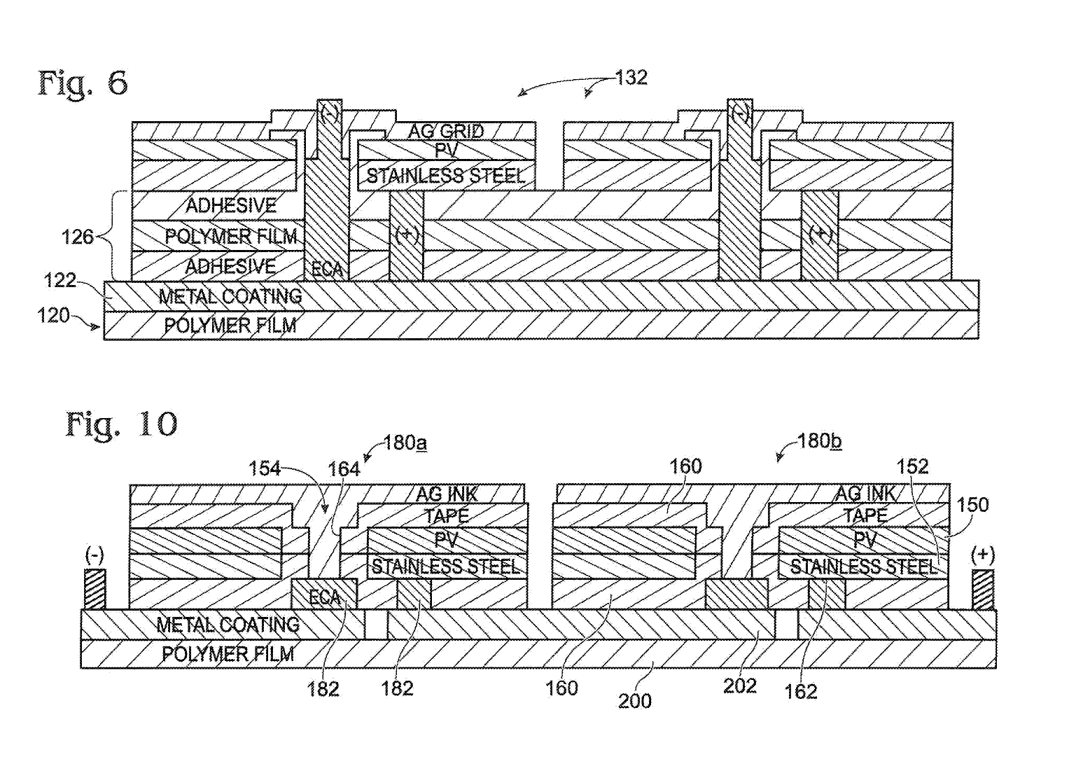

In steps 5 and 6 of FIG. 5, PV cells 132 are attached to the carrier web and then separated into strings of five cells connected to each other in electrical series. FIG. 6 shows a side cross-sectional view of two of these five adjacent cells attached to a carrier web according to the steps shown in FIG. 5. Note that FIG. 6 is substantially similar to the figures describing step 9 in FIG. 1B and step 8b in FIG. 2, except that the dielectric layer of FIGS. 1B and 2 has been replaced by double-sided tape layer 126 (adhesive/polymer film/adhesive) in FIG. 6. Holes in tape are lined up with cell apertures.

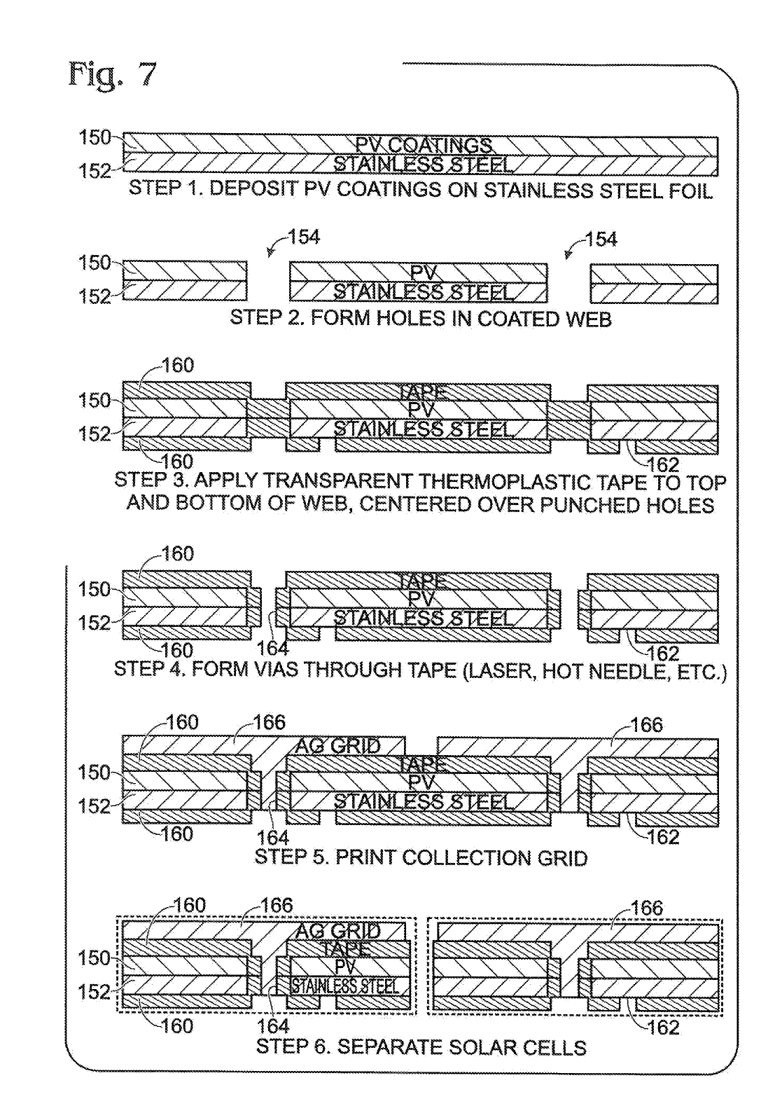

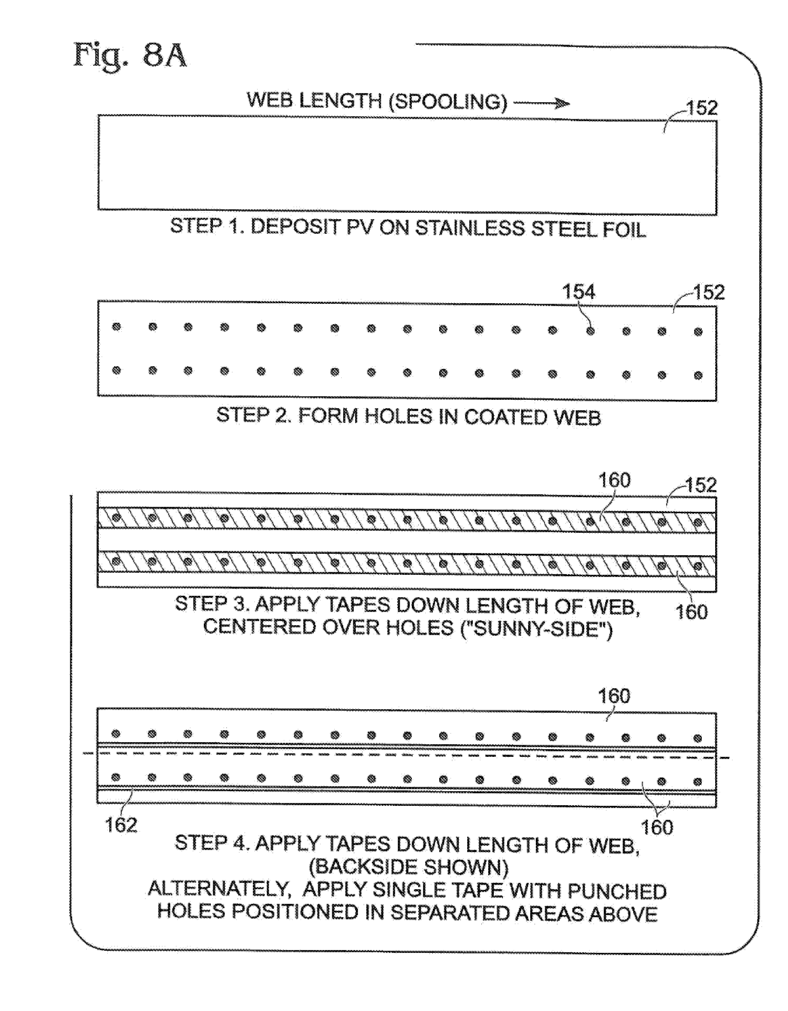

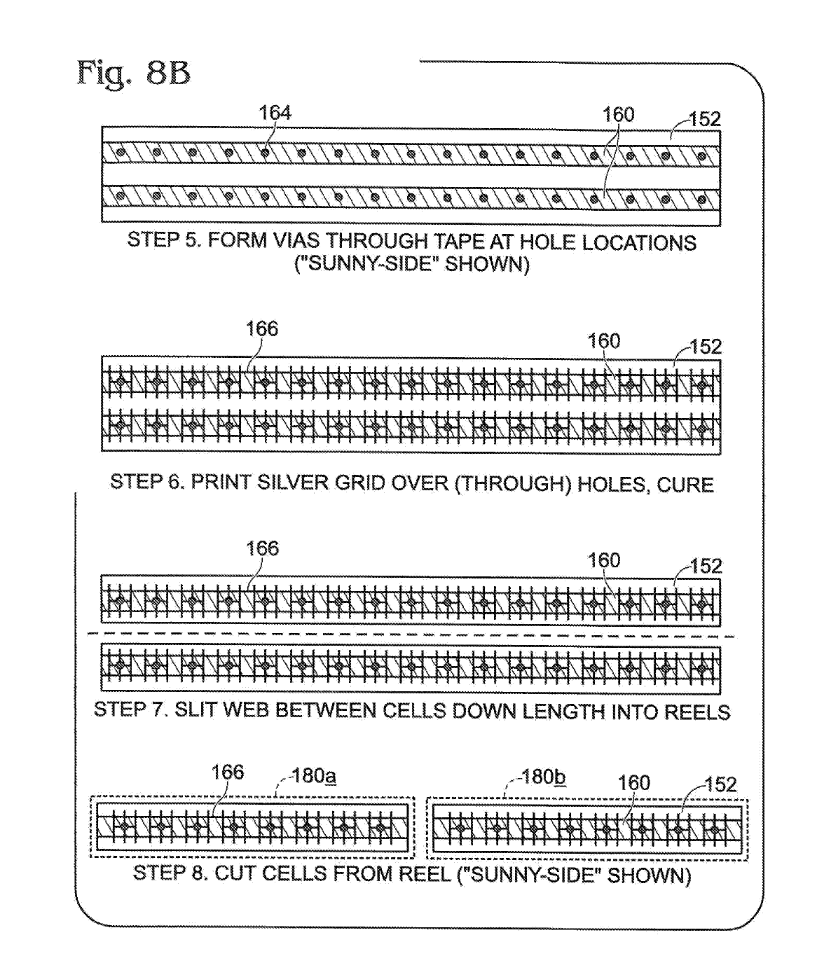

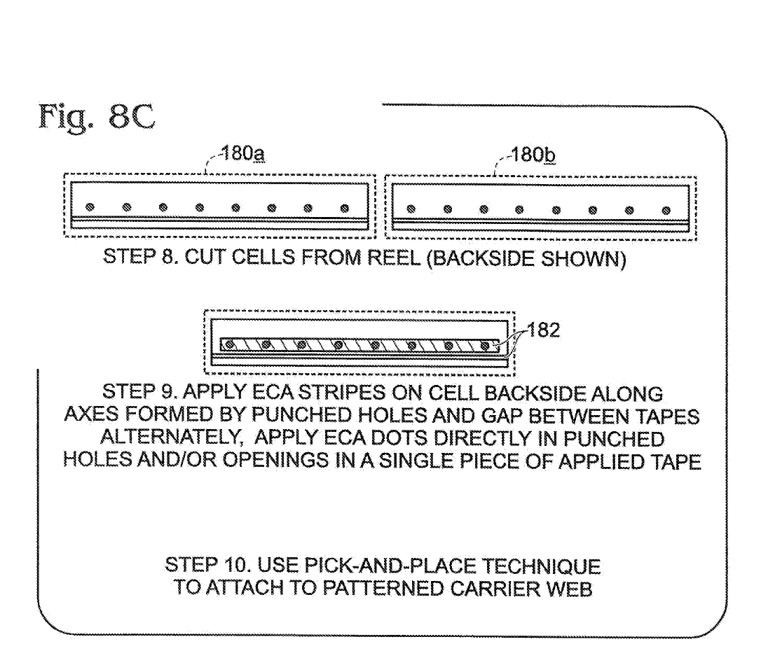

FIGS. 7-10 depict processing steps for an alternate embodiment of a string of thin-film PV cells, in which a thermoplastic tape is applied to the top and bottom sides of the cells. The thermoplastic tape serves a similar purpose as, and typically replaces, both the dielectric layer applied to the top surface of the PV cells at step 3 of FIG. 1 and the dielectric layer applied to the top surface of the carrier web at step 4 of FIG. 4. FIG. 7 includes a sequence of end cross-sectional views showing the processing steps of the alternate PV cell embodiment, and FIGS. 8A-C include a sequence of top and bottom views of these steps.

At steps 1-2 of FIG. 7, PV layers 150 are applied to substrate 152, and apertures 154 are formed extending from the top surface to the bottom surface of each cell. These steps are also depicted at steps 1-2 of FIG. 8A. At step 3 of FIG. 7, transparent thermoplastic tape 160 is applied to the top and bottom surfaces of the PV cell material, centered over the apertures on the top surface of the PV material, and asymmetrically on the bottom surface of the PV cell material to leave a gap 162 for establishing electrical contact between the bottom surface of each cell and an underlying carrier web that will eventually be integrated with the cells. Application of the tape to the top and bottom surfaces, showing the width of the tape strips relative to the PV web, is depicted at steps 3 and 4 of FIG. 8A, respectively. At step 4 of FIG. 7 and at step 5 of FIG. 8B, apertures (or vias) 164 are formed through the thermoplastic tape. This may be accomplished by any suitable method, such as with a laser or a heated needle.

At step 5 of FIG. 7 and at step 6 of FIG. 8B, a conductive collection grid 166, substantially similar to the grid applied at step 4 of FIG. 1A, is applied to the top surface of the PV material. As described previously, this grid is configured to collect electric current from the top surface of the PV cells, and may be constructed primarily from silver (Ag), a silver alloy, or any other suitably conductive metal or other material. The grid may be, for example, a silver-based ink deposited through a printing process. As indicated at step 5 of FIG. 7, the grid material may, when applied, extend partially down into apertures 164 formed in the PV cells and the thermoplastic tape.

At step 6 of FIG. 7 and at step 7 of FIG. 8B, the PV material is cut lengthwise to form two substantially similar reels. At step 8 of FIG. 8C, the reels are cut into individual PV cells 180a and 180b. Finally, at step 9 of FIG. 8C, electrically conductive adhesive 182 is applied to the bottom surface of each PV cell. The conductive adhesive is applied both along the axis formed by the apertures 154 in each cell, and also at the gap 162 between thermoplastic tape strips. This allows the conductive adhesive to be in electrical contact with both conductive grid 166 at the top surface of the cell (through the apertures), and also with the bottom surface of the cell (through the gap in the tape).

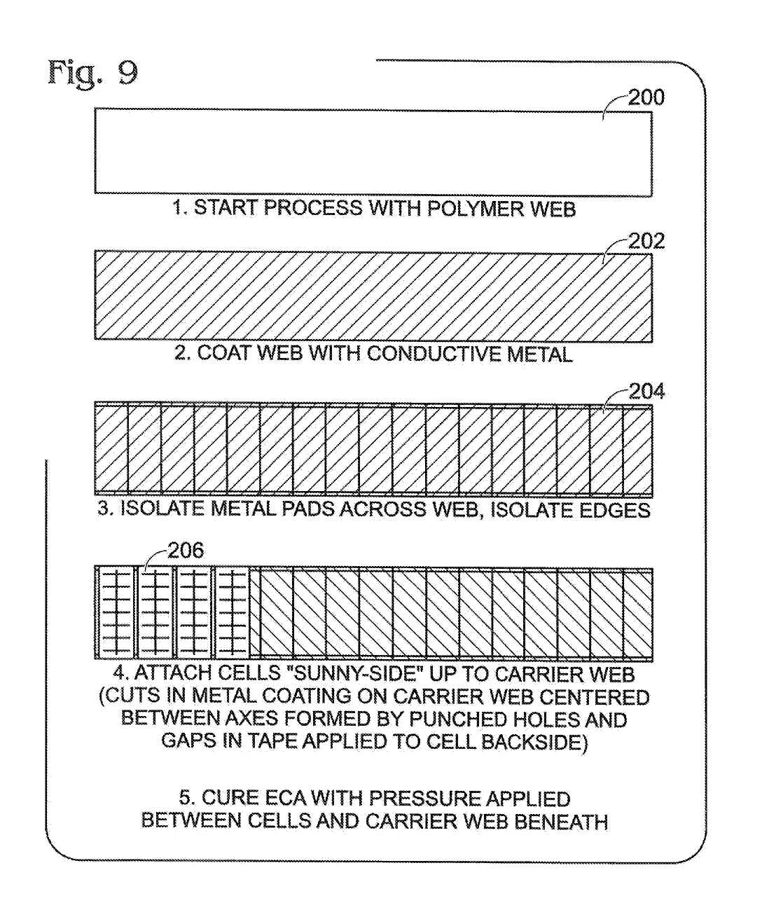

FIGS. 9-10 show the preparation of a conductive carrier web and its integration with PV cells formed in the manner described above with respect to FIGS. 7-8C. As indicated in steps 1-2 of FIG. 9, the carrier web typically includes polymer substrate 200 coated with conductive material 202 such as a metal. As shown in step 3 of FIG. 9, the conductive layer of the carrier web is divided into electrically isolated sections 204 disposed between the edges of the web, typically by scribing the metal to create isolated sections with desired dimensions. As shown at steps 6 and 7 of FIG. 9, PV cells 206 prepared in accordance with the steps depicted in FIGS. 7-8C then may be attached to the carrier web. The electrically conductive adhesive on the bottom surface of the cells bonds the cells to the carrier web, while establishing electrical contact between the carrier web and both sides of each cell. The adhesive may be cured, for example, by the application of pressure and/or heat.

As in the previously described embodiments and as depicted in FIG. 10, PV cells 180a and 180b of the present embodiment are attached to the carrier web so that each cell spans one of the scribed gaps in the carrier web. As a result, the top and bottom surfaces of each cell make electrical contact with the carrier web on opposite sides of a scribed gap. However, the positive polarity (bottom) side of a given cell and the negative polarity (top) side of the adjacent cell do not span a scribed gap, i.e., both contact the same electrically connected region of the carrier web. This results in a series connection between the adjacent cells. Also as depicted in FIG. 10, a string of serially connected cells may be prepared for integration into a circuit by attaching terminal connectors 210a and 210b at each end of the string. Although FIG. 10 depicts a string of only two adjacent cells, a string more generally includes any desired number of PV cells connected in electrical series.

The electrically conductive adhesive (ECA) suitable for use in the embodiments described above generally will be at least semi-flexible, and may be chosen to have various other advantageous properties. For example, the chosen ECA may be curable at a temperature less than 225 degrees Celsius (° C.), or in some cases less than 200° C., to avoid possible heat damage to other components of the cell. The ECA also may contain a corrosion inhibiting agent, to decrease the likelihood of corrosion during environmental exposure. ECAs suitable with the methods and apparatus described in this disclosure include, for example, a metallic/polymeric paste, an intrinsically conductive polymer, or any other suitable semi-flexible, electrically conductive adhesive material. In some cases, an epoxy resin, such as a bisphenol-A or bisphenol-B based resin, may be combined with a conductive filler such as silver, gold, or palladium to form an ECA. Alternative resins include urethanes, silicones, and various other thermosetting resins, and alternative conductive fillers include nickel, copper, carbon, and other metals, as well as metal coated fibers, spheres, glass, ceramics, or the like. Suitable corrosion inhibitors include heterocyclic or cyclic compounds and various silanes. Specific examples of compounds that may be appropriate include salicylaldehyde, glycidoxypropyltrimethoxysilane, 8-hydroxyquinoline, and various compounds similar to 8-hydroxyquinoline, among others.

Dielectric materials suitable for use in the embodiments described above may be constructed from any appropriate substance, such as an oxide- or fluoride-based material, a flexible acrylic UV thermosetting polymer, UV curable silicone, epoxy and urethane formulations, two-part formulations of a catalyst and a resin such as epoxy, acrylic, or urethane, and air-drying or air-cured silicones and urethanes, among others. Dielectric materials may be applied using printing, sputtering or any other suitable application technique.

A thin film or layer typically means a layer ranging in thickness from fractions of a nanometer up to approximately 5 micrometers in thickness. Photovoltaic cells or substrates may be described as flexible which typically means the substrate may be bent or rolled around a curved surface such as a mandrel having a diameter of between approximately 10-20 centimeters, without significantly compromising or destroying the functionality of the photovoltaic device.

The disclosure set forth above may encompass multiple distinct inventions with independent utility. Although each of these inventions has been disclosed in its preferred form(s), the specific embodiments thereof as disclosed and illustrated herein are not to be considered in a limiting sense, because numerous variations are possible. The subject matter of the inventions includes all novel and nonobvious combinations and subcombinations of the various elements, features, functions, and/or properties disclosed herein. The following claims particularly point out certain combinations and subcombinations regarded as novel and nonobvious. Inventions embodied in other combinations and subcombinations of features, functions, elements, and/or properties may be claimed in applications claiming priority from this or a related application. Such claims, whether directed to a different invention or to the same invention, and whether broader, narrower, equal, or different in scope to the original claims, also are regarded as included within the subject matter of the inventions of the present disclosure.

I claim:

1. A photovoltaic device comprising
first and second cells, each cell having a photovoltaic coating on a sheet creating a positive side and a negative side, the negative side of each cell having a conductive grid structure, and at least one hole along the grid structure, providing access between the positive and negative sides, wherein each hole has walls substantially covered by dielectric material,
a carrier having a mounting surface for electrically connecting the first and second cells in series, the carrier being configured to electrically connect the grid of the first cell to the positive side of the second cell via the hole in the first cell.

2. The photovoltaic device of claim 1, wherein the sheet is flexible.

3. The photovoltaic device of claim 1, wherein the sheet is conductive.

4. The photovoltaic device of claim 1, further comprising
electrically conductive adhesive connecting the grid of the first cell to the carrier.

5. The photovoltaic device of claim 1, wherein the carrier has a conductive region on the mounting surface, the conductive region running continuously across a gap between the first and second cells.

6. The photovoltaic device of claim 5, further comprising a dielectric layer separating the positive sides of the first and second cells from the conductive region of the carrier except for two openings which provide electrical connection, via a conductive material, from the conductive region of the carrier to the grid of the first cell, and from the conductive region of the carrier to the positive side of the second cell.

7. The photovoltaic device of claim 6, wherein the conductive material is an electrically conductive adhesive.

8. The photovoltaic device of claim 6, wherein the dielectric layer is a dielectric adhesive.

9. The photovoltaic device of claim 6, wherein the dielectric layer includes a layer of double sided dielectric tape.

10. The photovoltaic device of claim 1, wherein each of the first and second cells has layers of transparent thermoplastic tape applied to the positive and negative sides.

11. A string of thin film photovoltaic cells, comprising
a plurality of thin-film photovoltaic cells, each cell having a top surface, a bottom surface and at least one aperture extending from the top surface to the bottom surface, and
an electrically conductive carrier web underlying the bottom surface of the cells,
wherein the top surface of each cell is electrically connected to the carrier web through a first portion of electrically conductive adhesive disposed in the at least one aperture, and the bottom surface of each cell is electrically connected to the carrier web through a second portion electrically conductive adhesive disposed between the carrier web and the bottom surface of each cell.

12. The string of thin film photovoltaic cells of claim 11, further comprising dielectric material disposed within the at least one aperture of each cell to prevent electrical contact between the first portion of electrically conductive adhesive and an inner surface of the aperture.

13. The string of thin film photovoltaic cells of claim 12, further comprising an electrically conductive grid disposed along the top surface of each cell and configured to electrically connect the first portion of electrically conductive adhesive to the top surface of the cell.

14. The string of thin film photovoltaic cells of claim 11, wherein the carrier web includes a polymer substrate coated with a metallic thin film.

15. The string of thin film photovoltaic cells of claim 14, wherein the metallic thin film of the carrier web is divided into discrete sections, and wherein each discrete section is configured to span the bottom surfaces of two of the thin-film photovoltaic cells.

16. The string of thin film photovoltaic cells of claim 15, further comprising a double-sided adhesive tape disposed between the metallic thin film of the carrier web and the bottom surface of the photovoltaic cells.

17. The string of thin film photovoltaic cells of claim 16, wherein the double-sided adhesive tape includes first and second adhesive layers, and a dielectric disposed between the first and second adhesive layers.

18. The string of thin film photovoltaic cells of claim 17, wherein the double-sided adhesive tape includes a plurality of apertures filled configured to receive the second portion of electrically conductive adhesive.

19. A string of thin film photovoltaic cells, comprising:
a plurality of thin-film photovoltaic cells, each cell having a top surface, a bottom surface and at least one aperture extending from the top surface to the bottom surface;
a first layer of dielectric tape attached to the top surface of each cell and a second layer of dielectric tape attached to the bottom surface of each cell, wherein the dielectric tape extends at least partially through the at least one aperture and is configured to electrically insulate an inner surface of each aperture; and
an electrically conductive material disposed in a grid along the top surface of each cell, extending substantially through the at least one aperture of each cell, and configured to carry an electric current from the top surface of each cell through the at least one aperture toward the bottom surface of each cell.

20. The string of thin film photovoltaic cells of claim 19, further comprising an electrically conductive carrier web underlying the bottom surface of the cells.

21. The string of thin film photovoltaic cells of claim 20, further comprising a layer of electrically conductive adhesive disposed between the carrier web and the bottom surface of the cells and configured to electrically connect the carrier web to the electrically conductive material extending through each aperture.

22. The string of thin film photovoltaic cells of claim 20, wherein the carrier web includes a polymer substrate coated with a metallic thin film.

23. A solar cell array, comprising:
at least first and second thin film photovoltaic cells, each cell including a top surface, a bottom surface and an aperture extending from the top surface to the bottom surface;
an electrically conductive material disposed with the aperture of each cell and configured to transfer electric current from the top surface of each cell toward the bottom surface; and
an electrically conductive carrier web underlying the bottom surface of each cell and configured to connect the first and second cells in electrical series by making electrical contact with the electrically conductive material disposed within the aperture of the first cell and by making electrical contact with the bottom of the second cell.
